(19) United States
(12) Patent Application Publication
(10) Pub. No.: US 2008/0191334 A1
(43) Pub. Date: Aug. 14, 2008

(54) Glass dam structures for imaging devices chip scale package

(75) Inventors: Hsiao-Wen Lee, Hsinchu (TW); Jui-Ping Weng, Miaoli (TW)

Correspondence Address: Joe McKinney Muncy, PO Box 1364, Fairfax, VA, 22038-1364, US

(73) Assignee: VisEra Technologies Company Limited

(21) Appl. No.: 11/705,133

(22) Filed: Feb. 12, 2007

(51) Int. Cl. H01L 23/02

(52) U.S. Cl. 257/680; 257/E23.18

(57) ABSTRACT

Glass dam structures for imaging device chip scale package. An optoelectronic device chip scale package comprises a substrate configured as a support structure for the chip scale package. A semiconductor die with die circuitry is attached to the substrate. A glass encapsulant is disposed on the substrate encapsulating the semiconductor die, wherein the glass encapsulant has a dam structure around an opening. A seal layer is disposed between the substrate and the dam structure bonding the two together.

### BACKGROUND OF THE INVENTION

1. Field of the Invention

The invention relates to an optoelectronic device chip scale packages, and more particularly to a CMOS image sensor chip scale package.

2. Description of the Related Art

Microelectronic imagers are used in digital cameras, wireless devices with picture capabilities, and many other applications. Cell phones and Personal Digital Assistants (PDAs), for example, incorporate microelectronic imagers for capturing and sending digital images. The use of microelectronic imagers in electronic devices has been steadily increasing as imagers become smaller and produce higher quality images with increased pixel counts.

Microelectronic imagers include image sensors that use Charged Coupled Device (CCD) systems, Complementary Metal-Oxide Semiconductor (CMOS) systems, or other systems. CCD image sensors are widely used in digital cameras and other applications. CMOS image sensors are also becoming very popular due to low production cost, high yield, and small size, enabled by manufacture using technology and equipment developed for fabricating semiconductor devices. CMOS image sensors are accordingly “packaged” to protect their delicate components and provide external electrical contacts.

U.S. Pat. No. 6,777,767, the entirety of which is hereby incorporated by reference, discloses a packaged integrated circuit device and a method for producing the packaged integrated circuit device. FIGS. 1a-1e are cross sections of a conventional fabrication method. Referring to FIG. 1a, a photoresist layer 12 is formed on a transparent substrate 10 Referring to FIG. 1b, the photoresist layer 12 is patterned by a mask and etched to form spacers 14, typically rectangular, as indicated in FIG. 2. Specifically, FIG. 1b is a sectional diagram of FIG. 2 along lines A-A′.

Referring to FIG. 1c, a support substrate 20 with optoelectronic microstructure element 19 and contact pads (not shown) is provided. Adhesive 16 is applied adjacent to and between the spacers formed on the transparent substrate 10. Next, referring to FIG. 1d, the transparent substrate 10, serving as a packaging layer, thus prepared, is fixed to the support substrate 20. As seen clearly, a cavity 18 is defined between the transparent substrate 10 and the support substrate 20. Finally, as shown in FIG. 1e, the support substrate 20 is preferably thinned by grinding.

Conventional packaged optoelectronic microstructure elements can present increased manufacturing costs and process complexity. Since the photoreist layer 12 must be formed on the substrate 10 and patterned to form the spacers 14 defining the cavity 18, an additional photolithography step is employed, increasing costs and lowering throughput and yield. Therefore, there is a significant need to enhance the efficiency and reliability of packaging optoelectronic microstructure elements.

Conventional packaged optoelectronic microstructure elements also exhibit packages occupying a significant amount of vertical space since the spacers 14 with height H are additionally formed on the transparent substrate 10 to maintain a specific distance from the support substrate 20 to define the cavity 18. Accordingly, the increased vertical thickness of conventional packaged microelectronic imagers can be a limiting factor in the design and marketability of compact picture cell phones or PDAs. Therefore, there is a need to provide optoelectronic microstructure elements with smaller footprint and lower vertical profile.

### BRIEF SUMMARY OF THE INVENTION

A detailed description is given in the following embodiments with reference to the accompanying drawings. These and other problems are generally solved or circumvented, and technical advantages are generally achieved, by preferred illustrative embodiments of the invention, which provide a display device.

Optoelectronic device chip scale packages are provided. In this regard, an exemplary embodiment of such as optical microstructure plate comprises a substrate configured as a support structure for the chip scale package. A semiconductor die with die circuitry is attached to the substrate. A glass encapsulant is disposed on the substrate encapsulating the semiconductor die, wherein the glass encapsulant has a dam structure around an opening. A seal layer is disposed between the substrate and the dam structure bonding the two together.

Further, a CMOS image sensor chip scale package is also provided in the invention. An exemplary embodiment of such as CMOS image sensor chip scale package comprises a substrate configured as a support structure for the chip scale package. A CMOS image sensor die with die circuitry is attached to the substrate. A glass encapsulant is disposed on the substrate encapsulating the CMOS image sensor die, wherein the glass encapsulant has a dam structure around an opening. A seal layer is disposed between the substrate and the dam structure bonding the two together.

### BRIEF DESCRIPTION OF THE DRAWINGS

The invention can be more fully understood by reading the subsequent detailed description and examples with references made to the accompanying drawings, wherein:

FIGS. 1a to 1e are cross sections of a conventional method for fabricating a packaged integrated circuit device.

FIG. 2 is a schematic diagram of FIG. 1b.

FIGS. 3a to 3m are cross sections of a method for fabricating an optoelectronic device chip scale package of the invention.

FIG. 4 is a schematic diagram of FIG. 3b.

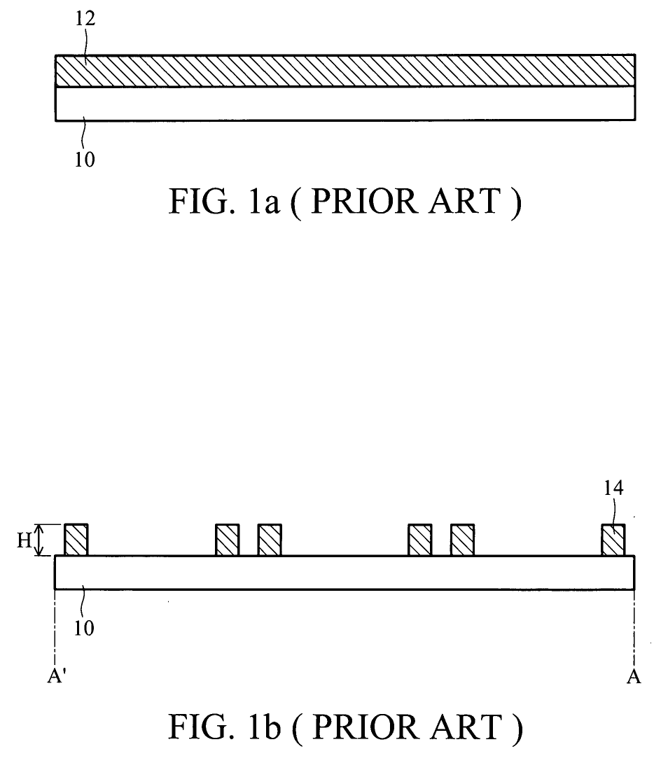

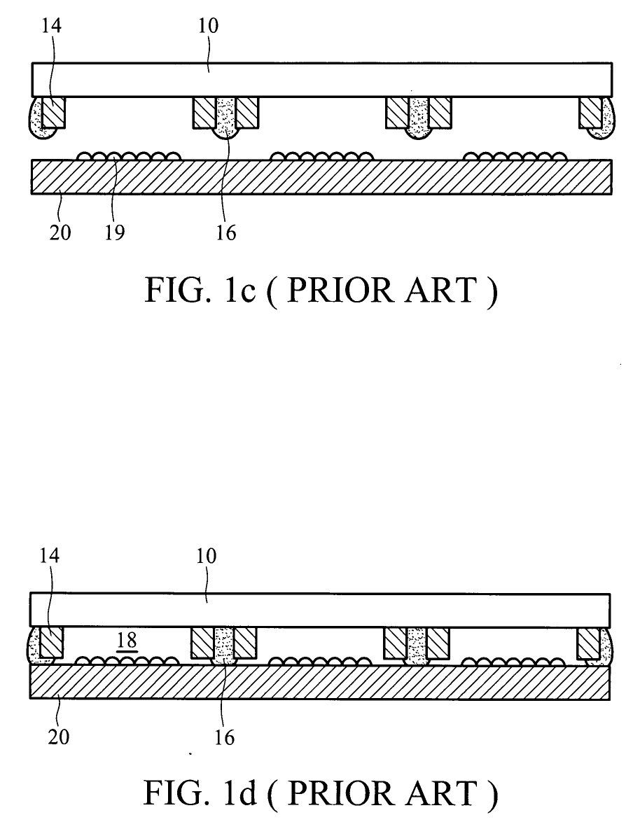

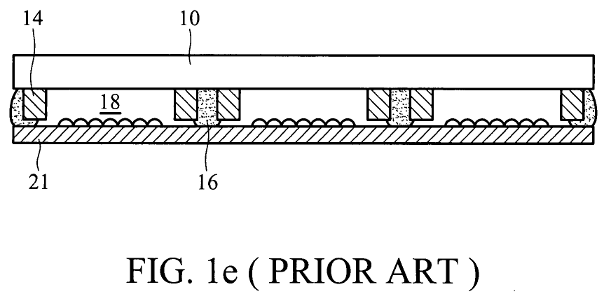

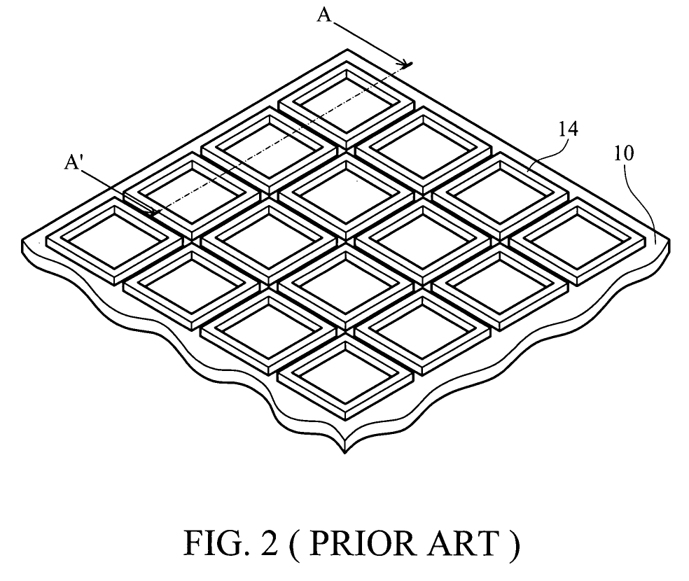

### DETAILED DESCRIPTION OF THE INVENTION

The following description is of the best-contemplated mode of carrying out the invention. This description is made for the purpose of illustrating the general principles of the invention and should not be taken in a limiting sense.

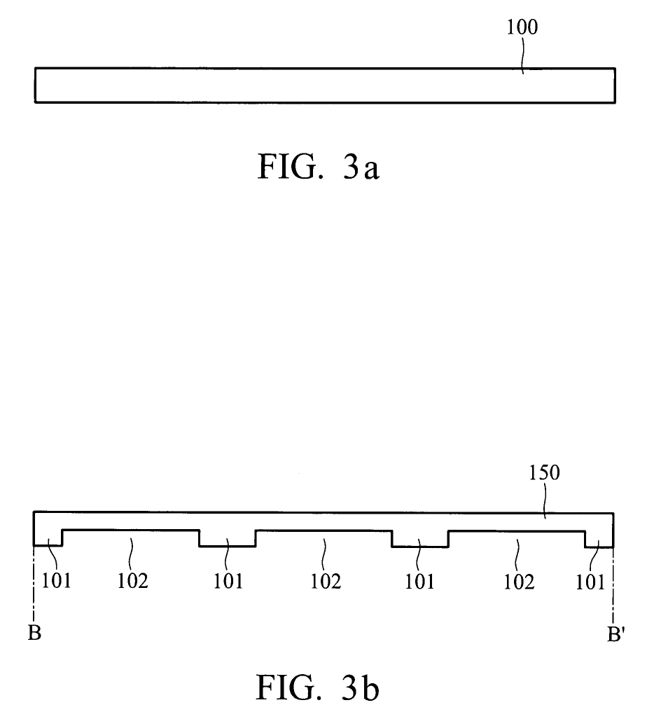

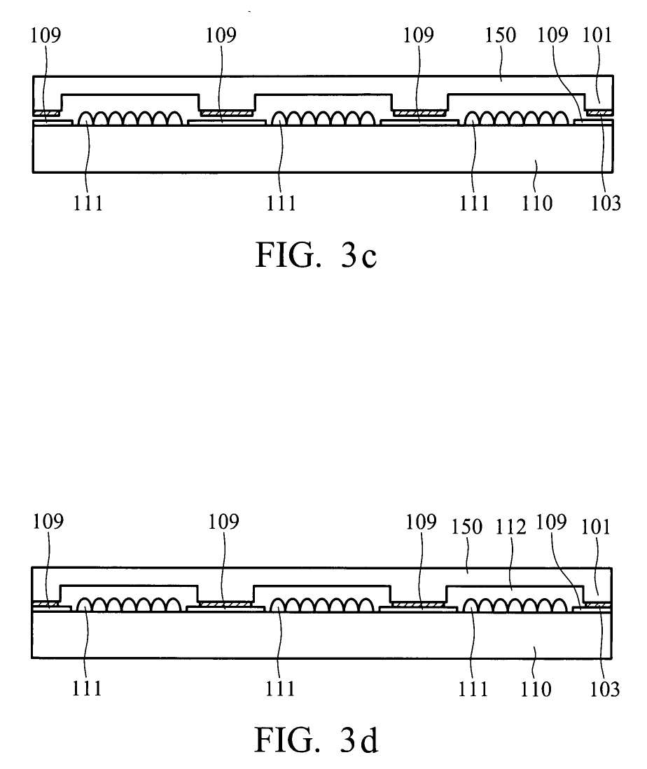

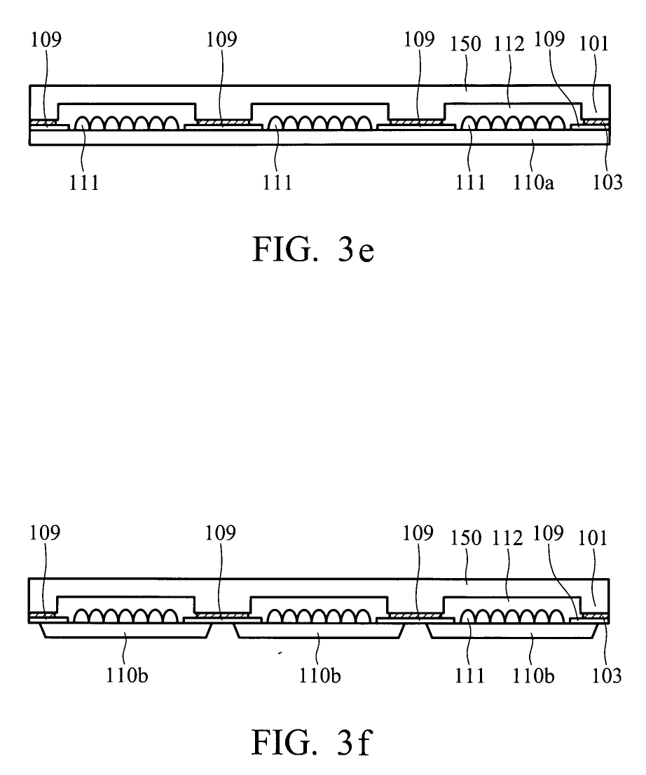

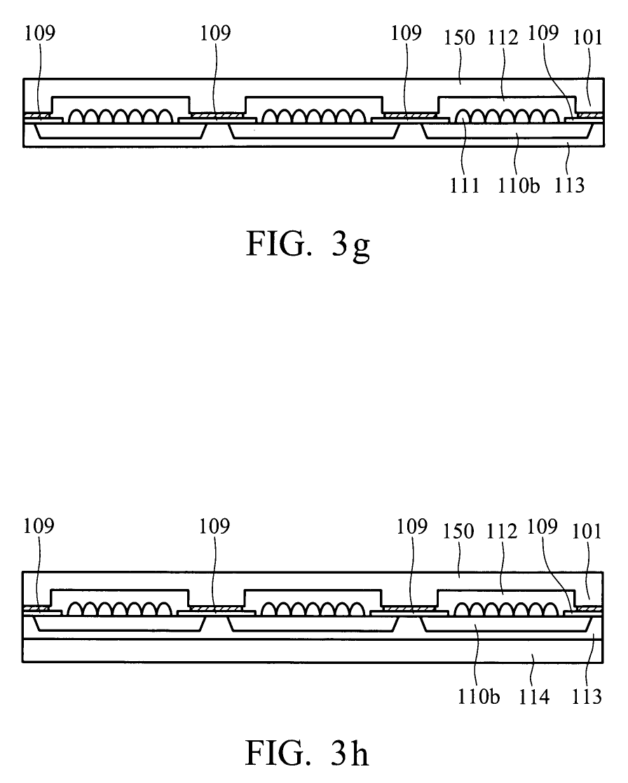

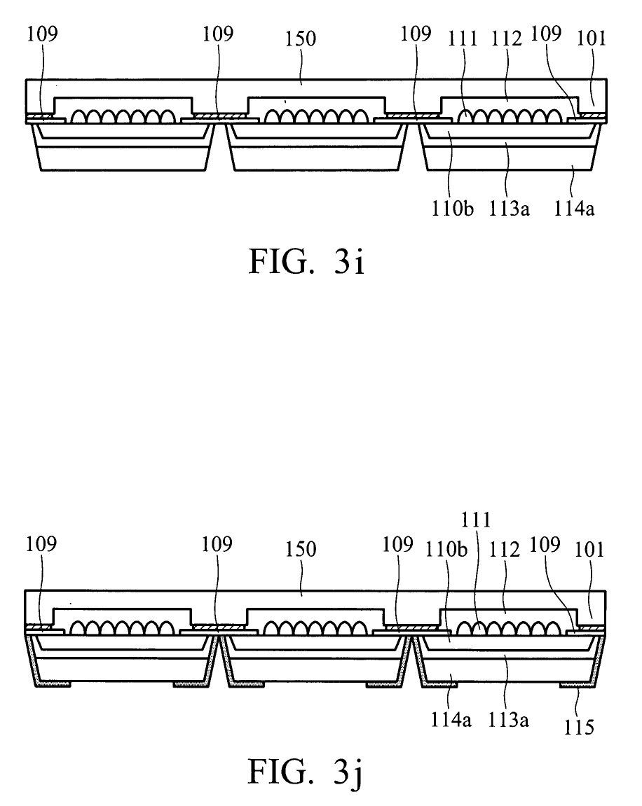

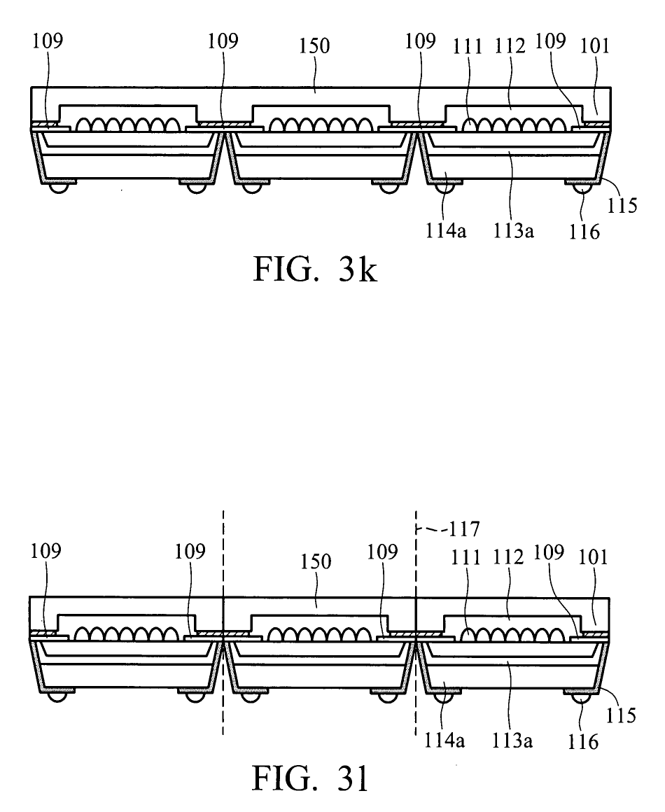

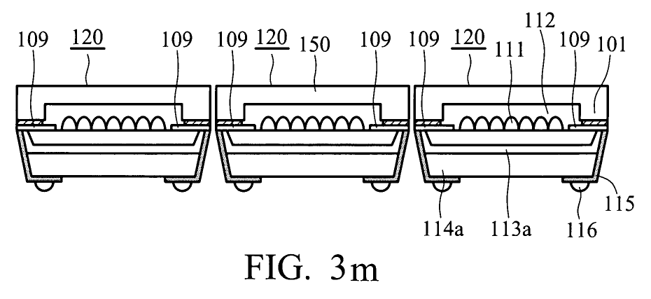

FIGS. 3a-3m are cross sections illustrating an exemplary embodiment of a method for fabricating a CMOS image sensor chip scale package of the invention.

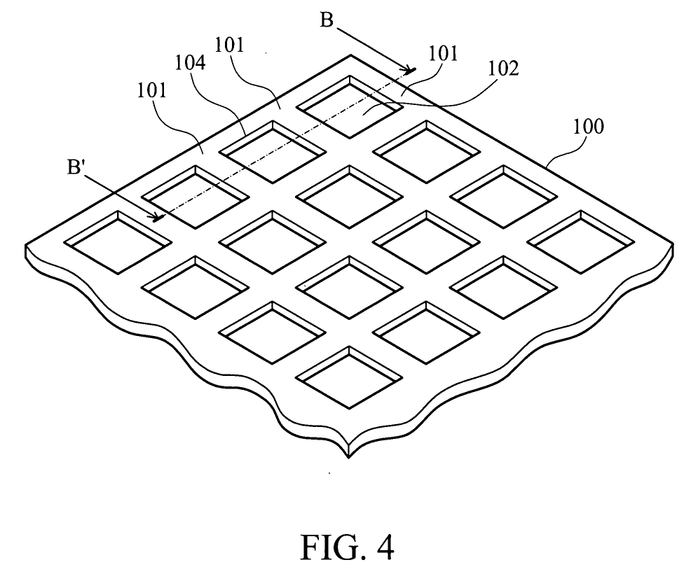

Referring to FIG. 3a, a glass substrate 100 is provided. Next, referring to FIG. 3b, the glass substrate 100 is partially removed by bulk micromachining to form a glass encapsulant 150 having openings 102 and dam structures 101 surrounding the opening 102. FIG. 4 is a schematic diagram of the glass encapsulant 150, and FIG. 3b is a sectional diagram of FIG. 4 along lines B-B′. Referring to FIG. 4, the profile of the sidewall 104 of the dam structure 101 is straight, and the opening 102 is square. In some embodiments of the invention, the profile of the sidewall 104 of the dam structure 101 can be sawtoothed, and the opening 102 can be polygonal. It should be noted that the dam structure 101 may has a specific height (between 10 μm and 200μm).

Referring to FIG. 3c, seal layers are formed on the dam structure 101 and a substrate 110 serving as a support substrate is provided, wherein the substrate 100 preferably comprises lens quality glass or quartz. A semiconductor die with die circuitry (not show) attached thereon is mounted on the transparent substrate. For example, a CMOS image sensor device die 111 is flip chip bonded on the transparent substrate 110. The CMOS image sensor device die 111comprises a sensor area with a micro-lens array configured as an image plane.

Referring to FIG. 3d, the glass encapsulant 150 is bonded on the substrate 110 by the seal layer 103 for encapsulating the CMOS image sensor device die 111, defining a cavity 112 therebetween. The seal layer 103 can be an adhesive layer. Furthermore, the seal layer 103 can be a silicon layer and the substrate 110 and the glass encapsulant 150 are bonding by anodic bonding. Moreover, the seal layer 103 is a metal layer (such as Au, Sn, or alloy thereof) and the substrate 110 and the glass encapsulant 150 are bonding by eutectic bonding.

Next, the support substrate 110 is thinned by grinding to form a thinner substrate 110a as shown in FIG. 3e, and then etched to define separate substrates 110b as shown in FIG. 3f. Following etching, the separate substrates 110b are fixed via an epoxy layer 113 to an underlying packaging layer 114, as shown in FIGS. 3g and 3h.

Referring to FIG. 3i, the packaging layer 114 and epoxy layer 113 are mechanically notched to form separate packaging layer 114a and separate epoxy layer 113a. Next, referring to FIG. 3j, electrical contacts 115 are formed on the separate packaging layer 114a and separate epoxy layer 113a and electrically connect to the die circuitry. Next, referring to FIG. 3k, contact bumps 116 are formed on the electrical contacts 115. Finally, the resulting assembly is cut along the cutting line 117 and subjected to a dicing process to yield a plurality of packaged integrated circuit devices 120, referring to FIGS. 3l and 3m.

Accordingly, since the glass encapsulant with dam structure provided by the invention is fabricated by bulk micromachining from a glass substrate rather than additionally forming a plurality of spacers thereon, the optoelectronic device chip scale package of the invention not only has lower vertical profiles but also reduced manufacturing cost and process complexity. Furthermore, the coefficient of thermal expansion (CTE) of glass is 10 times less than that of polymer, resulting in superior reliability. Moreover, since the glass encapsulant with dam structure provided by the invention is fabricated by bulk micromachining, the glass dam structure has better control than polymer dam.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An optoelectronic device chip scale package, comprising:
a substrate configured as a support structure for the chip scale package;
a semiconductor die with die circuitry attached to the substrate;
a glass encapsulant on the substrate encapsulating the semiconductor die,
wherein the glass encapsulant has a dam structure around an opening; and
a seal layer disposed between the substrate and the dam structure bonding the two together.

2. The optoelectronic device chip scale package as claimed in claim 1, wherein the dam structure and the opening are formed by bulk micromachining.

3. The optoelectronic device chip scale package as claimed in claim 1, wherein the profile of the sidewall of the dam structure is straight.

4. The optoelectronic device chip scale package as claimed in claim 1, wherein the profile of the sidewall of the dam structure is sawtoothed.

5. The optoelectronic device chip scale package as claimed in claim 1, wherein the opening is square.

6. The optoelectronic device chip scale package as claimed in claim 1, wherein the opening is polygonal.

7. The optoelectronic device chip scale package as claimed in claim 1, wherein the seal layer is an adhesive layer.

8. The optoelectronic device chip scale package as claimed in claim 1, wherein the seal layer is a silicon layer and the substrate and the dam structure are bonded by anodic bonding.

9. The optoelectronic device chip scale package as claimed in claim 1, wherein the seal layer is a metal layer and the substrate and the dam structure are bonded by eutectic bonding.

10. The optoelectronic device chip scale package as claimed in claim 1, wherein the dam structure provides a cavity between the substrate and the glass encapsulant.

11. A CMOS image sensor chip scale package, comprising:
a substrate configured as a support structure for the chip scale package;
a CMOS image sensor die with die circuitry attached to the substrate;
a glass encapsulant on the substrate encapsulating the CMOS image sensor die, wherein the glass encapsulant has a dam structure around an opening; and
a seal layer disposed between the substrate and the darn structure bonding the two together.

12. The CMOS image sensor chip scale package as claimed in claim 11, wherein the dam structure and the opening are formed by bulk micromachining.

13. The CMOS image sensor chip scale package as claimed in claim 11, wherein the profile of the sidewall of the dam structure is straight.

14. The CMOS image sensor chip scale package as claimed in claim 11, wherein the profile of the sidewall of the dam structure is sawtoothed.

15. The CMOS image sensor chip scale package as claimed in claim 11, wherein the opening is square.

16. The CMOS image sensor chip scale package as claimed in claim 11, wherein the opening is polygonal.

17. The CMOS image sensor chip scale package as claimed in claim 11, wherein the seal layer is an adhesive layer.

18. The CMOS image sensor chip scale package as claimed in claim 11, wherein the seal layer is a silicon layer and the substrate and the dam structure are bonded by anodic bonding.

19. The CMOS image sensor chip scale package as claimed in claim 11, wherein the seal layer is a metal layer and the substrate and the dam structure are bonded by eutectic bonding.

20. The CMOS image sensor chip scale package as claimed in claim 11, wherein the dam structure provides a cavity between the substrate and the glass encapsulant.
